(19) United States
(12) Patent Application Publication
(10) Pub. No.: US 2023/0290756 A1
(43) Pub. Date: Sep. 14, 2023

(54) PACKAGE STRUCTURE OF EMBEDDED POWER MODULE WITH LOW PARASITIC INDUCTANCE AND HIGH HEAT DISSIPATION EFFICIENCY

(71) Applicant: Zhejiang University, Hangzhou (CN)

(72) Inventors: Xinnan Sun, Hangzhou (CN); Min Chen, Hangzhou (CN); Bodong Li, Hangzhou (CN); Xiaoqing Wang, Hangzhou (CN); Dongbo Zhang, Hangzhou (CN)

(21) Appl. No.: 17/752,849

(22) Filed: May 24, 2022

(30) Foreign Application Priority Data
Mar. 9, 2022 (CN) 202210221535.6

(51) Int. Cl. H01L 25/07; H01L 23/31; H01L 23/498; H01L 23/538

(52) U.S. Cl. CPC H01L 25/072; H01L 23/3107; H01L 23/49811; H01L 23/5389

(57) ABSTRACT

A package structure of an embedded power module includes a top insulation layer, a top metal pattern layer, a solder layer, a device layer, a bottom metal pattern layer and a bottom insulation layer sequentially arranged from top to bottom. The device layer includes at least two MOSFET bare dies and several metal connection blocks, and is filled with insulation filler to isolate the MOSFET bare dies and the metal connection blocks from each other. The drain electrodes of the bare dies are connected with the top metal pattern layer through the solder layer, and the source electrodes and the gate electrodes of the bare dies are electrically connected to the bottom metal pattern layer, respectively. The upper and lower surfaces of the metal connection blocks are electrically connected to the top metal pattern layer and the bottom metal pattern layer, respectively.

### CROSS REFERENCE TO RELATED APPLICATIONS

The present application claims the benefit of Chinese Patent Application No. 202210221535.6 filed on Mar. 9, 2022, the contents of which are incorporated herein by reference in their entirety.

### FIELD

The present application is applied in the technical field of power semiconductor device packaging, and more particularly relates to a package structure of an embedded power module with low parasitic inductance and high heat dissipation efficiency.

### BACKGROUND

High-efficiency and high-quality power conversion is the goal of the development of power electronic technology, so power modules are required to develop in the direction of small size, light weight, high efficiency, and high power. Under this development trend, the new generation of wide-bandgap semiconductor devices represented by silicon carbide show the superior performance such as fast switching speed, high thermal conductivity, etc. thereby contributing to its high-frequency and high-temperature applications, and playing an important role in greatly improving the power density of the converter.

The typical package structure based on substrate and bonding wire is used in most power modules in the current production (as shown in FIG. 1). The bottom of the power bare die is connected to the direct bonding copper (DBC) substrate through solder, and the top is connected to the DBC through bonding wire. The bonding wire and the upper copper rail of the DBC realize electrical interconnection, and DBC realizes electrical insulation and thermal management. In this package structure, the bonding wire has relatively large parasitic inductance, and the heat generated by the power devices can only be dissipated through the bottom of the package. The high-frequency applications of the power devices make them more sensitive to parasitic parameters. Under the same parasitic inductance, more serious problems such as overvoltage, parasitic oscillation, EMI, etc. will occur. The improvement of power level also makes the devices generate higher heat during operation. The heat cannot be dissipated in time under a single heat dissipation path, thereby affecting the overall reliability of the power module. Therefore, the traditional packaging mode can no longer meet the requirements of high-frequency and high-temperature applications of the power module. In order to solve the above problems, those skilled in the art have successively proposed technologies such as DBC+PCB hybrid packaging, three-dimensional packaging, chip front plane interconnection packaging, and the like. However, these packaging processes have the problems of complex structure, high cost, etc., so it is difficult to promote their applications in actual production.

Since the packaging technology has become the bottleneck problem of the development of the power module to high frequency and high temperature, new solutions with low parasitic inductance and efficient cooling need to be developed to promote the development of power module.

### SUMMARY

The technical problem to be solved by the disclosure is to overcome the deficiencies in the prior art and provide a package structure of an embedded power module with low parasitic inductance and high heat dissipation efficiency.

In order to solve the above problem, the application proposes the following solutions for implementation.

Provided is a package structure of an embedded power module with low parasitic inductance and high heat dissipation efficiency, which comprises a top insulation layer, a top metal pattern layer, a solder layer, a device layer, a bottom metal pattern layer and a bottom insulation layer sequentially arranged from top to bottom. Both the top insulation layer and the bottom insulation layer have partial openings. The exposed parts of the top metal pattern layer and the bottom metal pattern layer at the opening positions serve as a top electrode terminal and a bottom electrode terminal, respectively.

The device layer comprises at least two MOSFET bare dies and several metal connection blocks, and is filled with insulation filler to isolate the MOSFET bare dies and the metal connection blocks from each other.

The drain electrodes of the MOSFET bare dies are connected with the top metal pattern layer through the solder layer. The source electrodes and the gate electrodes of the MOSFET bare dies are electrically connected to the bottom metal pattern layer respectively. The upper and lower surfaces of the metal connection blocks are electrically connected to the top metal pattern layer and the bottom metal pattern layer, respectively.

As a preferred solution of the application, the insulation filler is further extended and filled between the MOSFET bare dies and the bottom metal pattern layer, and blind vias are provided in the insulation filler between them. A metal plating layer is provided on the inner wall of each blind via. The source electrodes and the gate electrodes are electrically connected to the bottom metal pattern layer through the metal plating layer, respectively.

As a preferred solution of the application, the insulation filler is further extended and filled between the metal connection blocks and the bottom metal pattern layer, and blind vias are provided in the insulation filler between them. A metal plating layer is provided on the inner wall of each blind via. The metal connection blocks are electrically connected to the bottom metal pattern layer through the metal plating layer.

As a preferred solution of the application, the upper surfaces of the metal connection blocks are connected to the top metal pattern layer through the solder layer.

As a preferred solution of the application, the metal connection blocks have the same height as that of the MOSFET bare dies.

As a preferred solution of the application, the insulation filler is further extended and filled to the vacant portion of the top metal pattern layer, and is connected with the lower surface of the top insulation layer. Alternatively, the insulation filler is further extended and filled to the vacant portion of the bottom metal pattern layer, and is connected with the upper surface of the bottom insulation layer.

As a preferred solution of the application, the top insulation layer is further extended downward and filled to the vacant portion of the top metal pattern layer, and is connected with the insulation filler in the device layer. Alternatively, the bottom insulation layer is further extended upward and filled to the vacant portion of the top metal pattern layer, and is connected with the insulation filler in the device layer.

As a preferred solution of the application, the embedded power module entirely presents a multi-layer plate-like structure.

As a preferred solution of the application, there is a plurality of top electrode terminals and bottom electrode terminals, respectively.

Compared with the prior art, the application has the following benefits.

1. The application reduces the packaging volume and weight of the power module and improves the power density of the module by embedding the power bare dies into the insulation material.

2. The application does not need to use bonding wires and electrode leads, which effectively reduces the parasitic inductance of the power module.

3. The application adopts the mode of placing the dies face down, further reduces the parasitic inductance of gate and source, effectively improves the switching speed of the power device, and reduces the interference of driving signal.

4. The application has double-sided electrode terminals, and can further integrate decoupling capacitors or other components for the power module, so as to further improve the performance and flexibility of the power module.

5. In the application, the metal connection block structure enhances the current carrying capacity of the power module and avoids temperature rise due to overcurrent. The design of the double-sided metal pattern layer enables the power module to realize double-sided heat dissipation, and improves the heat dissipation efficiency of the power module.

6. Based on the above advantages, the application is suitable for the application of the power module in the high power density, high frequency and high temperature working environment.

### BRIEF DESCRIPTION OF THE DRAWINGS

FIG. 1 is a typical package structure based on substrate and bonding wire in the prior art.

FIG. 2 is a schematic diagram of the package structure of an embedded power module with low parasitic inductance and efficient thermal management according to an embodiment of the application.

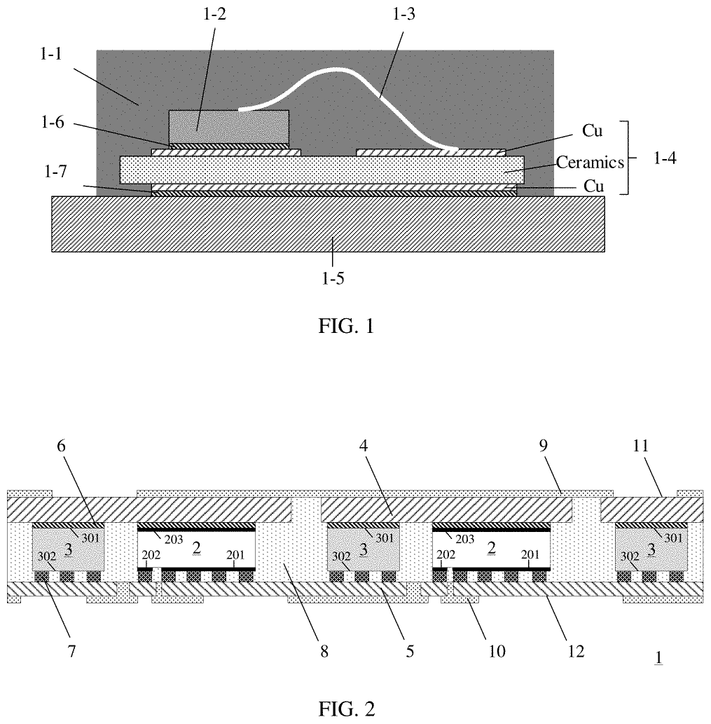

The description of reference signs in FIG. 1: 1-1 Packaging material; 1-2 Power bare die; 1-3 Bonding wire; 1-4 Direct Bonding Copper (DBC) substrate; 1-5 Heat dissipation substrate; 1-6 DBC solder; and 1-7 Solder.

The description of reference signs in FIG. 2: 1 Power module; 2 MOSFET bare die; 201 Source electrode; 202 Gate electrode; 203 Drain electrode; 3 Metal connection block; 301 Upper surface of the metal connection block; 302 Lower surface of the metal connection block; 4 Top metal pattern layer; 5 Bottom metal pattern layer; 6 Solder layer; 7 Blind via; 8 Device layer; 9 Top insulation layer; 10 Bottom insulation layer; 11 Top electrode terminal; and 12 Bottom electrode terminal.

### DETAILED DESCRIPTION OF THE EMBODIMENTS

The specific implementations of the application will be further described in detail below in combination with the accompanying drawings. In order to illustrate the technical solutions in the embodiments of the application more clearly, the following briefly introduces the drawings that need to be used in the description of the embodiments. Obviously, the drawings in the following description are only some embodiments of the present application. For those of ordinary skill in the art, other drawings can also be obtained from these drawings without creative effort. The specific embodiments are to further describe the application, but the protection scope of the application is not limited thereto.

As shown in FIG. 2, the package structure of an embedded power module of the application comprises a top insulation layer 9, a top metal pattern layer 4, a solder layer 6, a device layer 8, a bottom metal pattern layer 5 and a bottom insulation layer 10 sequentially arranged from top to bottom. Thus, this power module entirely presents a multi-layer plate-like structure. Both the top insulation layer 9 and the bottom insulation layer 10 have partial openings. The exposed parts of the top metal pattern layer 4 and the bottom metal pattern layer 5 at the opening positions serve as a top electrode terminal 11 and a bottom electrode terminal 12, respectively.

The device layer 8 comprises at least two MOSFET bare dies 2 and several metal connection blocks 3, and is filled with insulation filler to isolate the MOSFET bare dies 2 and the metal connection blocks 3 from each other. The drain electrodes 203 of the MOSFET bare dies 2 are connected with the top metal pattern layer 4 through the solder layer 6, and the source electrodes 201 and gate electrodes 202 are electrically connected to the bottom metal pattern layer 5, respectively. The upper and lower surfaces of the metal connection blocks 3 are electrically connected to the top metal pattern layer 4 and the bottom metal pattern layer 5, respectively. The insulation filler is further extended and filled between the MOSFET bare dies 2 and the bottom metal pattern layer 5, and blind vias are provided in the insulation filler between the MOSFET bare dies 2 and the bottom metal pattern layer 5. A metal plating layer is provided on the inner wall of each blind via. The source electrodes 201 and the gate electrodes 202 are electrically connected to the bottom metal pattern layer 5 through the metal plating layer, respectively. Similarly, the insulation filler is further extended and filled between the metal connection blocks 3 and the bottom metal pattern layer 5, and blind vias are provided in the insulation filler between the metal connection blocks 3 and the bottom metal pattern layer 5. A metal plating layer is provided on the inner wall of each blind via. The metal connection blocks 3 are electrically connected to the bottom metal pattern layer 5 through the metal plating layer. The upper surfaces of the metal connection blocks 3 are connected to the top metal pattern layer 4 through the solder layer 6. The metal connection blocks 3 optionally have the same height as that of the MOSFET bare dies 2, and thus, the blind vias below the metal connection blocks 3 and the MOSFET bare dies 2 also have the same height.

Optionally, the insulation filler is further extended and filled to a vacant portion of the top metal pattern layer 4, and is connected with the lower surface of the top insulation layer 9 (as shown in FIG. 2). Alternatively, the insulation filler is further extended and filled to a vacant portion of the bottom metal layer 5, and is connected with the upper surface of the bottom insulation layer 10 (not shown in the figure). Optionally, the top insulation layer 9 is further extended downward and filled to the vacant portion of the top metal pattern layer 4, and is connected with the insulation filler in the device layer 8 (not shown in the figure). Alternatively, the bottom insulation layer 10 is further extended upward and filled to the vacant portion of the top metal pattern layer 4, and is connected with the insulation filler in the device layer 8 (as shown in FIG. 2).

In the application, the MOSFET bare dies 2 are provided with the source electrodes 201 and the gate electrodes 202 downwardly on the front side, and are provided with the drain electrodes 203 upwardly on the back side. As the prior art, optional example products include CREE's CPM2-1200-0080B, etc. Multiple MOSFET bare dies 2 can form different electrical connection relationships to realize the corresponding functions of the power module. The front faces of the MOSFET bare dies 2 are downward, which can shorten the distance from the source electrodes 201 and the gate electrodes 202 of the dies to the bottom electrode terminals of the power module and the circuit board, thus reducing the parasitic inductance of drive circuit. Specifically, the MOSFET bare dies 2 can be silicon-based or silicon-carbide-based, or other power bare dies such as IGBTs, etc.

The top metal pattern layer 4 and the bottom metal pattern layer 5 refer to patterned metal layers for electrical connection. The specific patterns are determined according to the function of the module and the connection mode of the dies. The example in FIG. 2 is a half-bridge structure composed of two dies connected in series.

The metal connection blocks 3 are used to realize the electrical connection between the top metal pattern layer 4 and the bottom metal pattern layer 5, and the specific arrangement mode depends on the function of the power module, which can be flexibly changed according to different functions. For example, the role of the “separately arranged” metal connection block 3 on the right side in FIG. 2 is to lead the electrode on the right lower surface of the power module to the terminal on the top surface to integrate components such as decoupling capacitor, etc. The upper surface and the lower surface of the metal connection block 3 are connected to the metal pattern layer respectively by solder layer and the metal plating layer poured into the blind via, which is determined by the packaging implementation process.

There may be a plurality of top electrode terminals 11 and bottom electrode terminals 12, respectively, and the specific number and position are determined according to the function and requirements of the power module, which are not limited in the application. In FIG. 2, a half-bridge module composed of two MOSFETs connected in series is taken as an example. Five electrode terminals of the half-bridge structure are arranged at the bottom, and two electrode terminals are arranged at the top to connect an absorption capacitor. In actual production, the specific positions of the terminals are determined by the design scheme of the metal pattern layer. As an application example, the bottom electrode terminals 12 can be used to connect to the circuit board, and the top electrode terminals 11 can be connected to a component such as a decoupling capacitor, etc.

Exemplary description of the manufacturing process of the package structure of an embedded power module in the application is indicated as follows:
1. producing the top metal pattern layer on a carrier;
2. welding bare dies and metal connection blocks;
3. laminating the plastic packaging material and the bottom metal pattern layer;
4. drilling vias and metalizing the blind vias; and
5. removing the carrier, processing top and bottom insulation layers, and treating the terminal surfaces.

In summary, through the chip-embedded design of double-sided heat dissipation without bonding wires or lead wires, the application realizes a package structure with low parasitic inductance and high heat dissipation efficiency by applying micro-vias, electroplating and other PCB processes, which has characteristics of low cost, high flexibility and easy development. The power module based on the embedded package has the advantages of small size, light weight, no bonding wire, double-sided heat dissipation, etc., and is a solution with great development potential.

1. A package structure of an embedded power module with low parasitic inductance and high heat dissipation efficiency, comprising a top insulation layer (9), a top metal pattern layer (4), a solder layer (6), a device layer (8), a bottom metal pattern layer (5) and a bottom insulation layer (10) sequentially arranged from top to bottom, wherein both the top insulation layer (9) and the bottom insulation layer (10) have partial openings, and exposed parts of the top metal pattern layer (4) and the bottom metal pattern layer (5) at opening positions serve as a top electrode terminal (11) and a bottom electrode terminal (12), respectively;
the device layer (8) comprises at least two MOSFET bare dies (2) and several metal connection blocks (3), and is filled with insulation filler between the MOSFET bare dies (2) and the metal connection blocks (3) to isolate the MOSFET bare dies (2) and the metal connection blocks (3) from each other; and
drain electrodes (203) of the MOSFET bare dies (2) are connected with the top metal pattern layer (4) through the solder layer (6), source electrodes (201) and gate electrodes (202) of the MOSFET bare dies (2) are electrically connected to the bottom metal pattern layer (5), respectively, and upper and lower surfaces of the metal connection blocks (3) are electrically connected to the top metal pattern layer (4) and the bottom metal pattern layer (5), respectively.

2. The package structure of the embedded power module according to claim 1, wherein the insulation filler is further extended and filled between the MOSFET bare dies (2) and the bottom metal pattern layer (5), and blind vias are provided in the insulation filler between the MOSFET bare dies (2) and the bottom metal pattern layer (5), a metal plating layer is provided on an inner wall of each blind via, and the source electrodes (201) and the gate electrodes (202) are electrically connected to the bottom metal pattern layer (5) through the metal plating layer, respectively.

3. The package structure of the embedded power module according to claim 1, wherein the insulation filler is further extended and filled between the metal connection blocks (3) and the bottom metal pattern layer (5), and blind vias are provided in the insulation filler between the metal connection blocks (3) and the bottom metal pattern layer (5), a metal plating layer is provided on an inner wall of each blind via, and the metal connection blocks (3) are electrically connected to the bottom metal pattern layer (5) through the metal plating layer.

4. The package structure of the embedded power module according to claim 1, wherein the upper surfaces of the metal connection blocks (3) are connected to the top metal pattern layer (4) through the solder layer (6).

5. The package structure of the embedded power module according to claim 1, wherein the metal connection blocks (3) have the same height as that of the MOSFET bare dies (2).

6. The package structure of the embedded power module according to claim 1, wherein the insulation filler is further extended and filled to a vacant portion of the top metal pattern layer (4), and is connected with a lower surface of the top insulation layer (9); or the insulation filler is further extended and filled to a vacant portion of the bottom metal pattern layer (5), and is connected with an upper surface of the bottom insulation layer (10).

7. The package structure of the embedded power module according to claim 1, wherein the top insulation layer (9) is further extended downward and filled to a vacant portion of the top metal pattern layer (4), and is connected with the insulation filler in the device layer (8); or the bottom insulation layer (10) is further extended upward and filled to a vacant portion of the top metal pattern layer (4), and is connected with the insulation filler in the device layer (8).

8. The package structure of the embedded power module according to claim 1, wherein the power module entirely presents a multi-layer plate-like structure.

9. The package structure of the embedded power module according to claim 1, wherein there is a plurality of top electrode terminals (11) and bottom electrode terminals (12), respectively.
